(19) United States
(12) Patent Application Publication
(10) Pub. No.: US 2005/0081791 A1
(43) Pub. Date: Apr. 21, 2005

(54) Vacuum treatment installation for flat rectangular or square substrates

(76) Inventors: Ralph Lindenberg, Schoneck (DE); Frank Fuchs, Geiselbach-Ommersbach (DE); Uwe Schussler, Aschaffenburg (DE); Stefan Bangert, Steinau (DE); Tobias Stolley, Frankfurt (DE)

Correspondence Address: FULBRIGHT & JAWORSKI, LLP, 666 FIFTH AVE, NEW YORK, NY, 10103-3198, US

(21) Appl. No.: 10/932,563

(22) Filed: Sep. 2, 2004

(30) Foreign Application Priority Data
Oct. 17, 2003 (DE) 103 48 281.4-45

(51) Int. Cl. C23C 16/00

(52) U.S. Cl. 118/728

(57) ABSTRACT

A vacuum treatment installation is provided for flat substrates of large edge lengths, which are conducted to and treated in an at least substantially perpendicular position. The treatment installation comprises a vacuum chamber with at least two treatment chambers, distributed over the circumference and open at the chamber side, a series of interlocks and a rotatable configuration of substrate holders (13) within the vacuum chamber with a driving mechanism (1) for the sequential rotation and radial movement of the substrate holders (13) relative to the treatment chambers. In order to decrease the placement area, the chamber volumes and the evacuation times, to simplify the “handling”, and especially to decrease the contamination hazard of the substrates by spalled-off layer particles, it is proposed that the substrate holders (13) are connected to the driving mechanism (1) in their lower regions via connecting rods (8), and that at least the lower pivot bearings of the connecting rod configurations (8) are disposed below a horizontal center line (M) of the height (H) of the bearing surface of the substrate holders (13). All pivot bearings are preferably disposed below the horizontal center line (M). Alternatively, parallelogram connecting rod configurations suspended on extension arms (4) can be disposed or trapezoidal connecting rod configurations can be placed onto a rotary table. The substrate transport takes place free of frames and preferably in the upward direction sloped at an angle between 1 and 20 degrees with respect to the rotational axis.

The invention relates to a vacuum treatment installation for flat rectangular or square substrates in an at least substantially perpendicular position, comprising a vacuum chamber with at least two treatment chambers distributed on the circumference of the vacuum chamber and open at the chamber side, a charging interlock, a discharging interlock and a rotatable arrangement of substrate holders within the vacuum chamber, with a driving mechanism for the sequential rotation and the advance and retraction of the substrate holders relative to the treatment chambers.

Continuously operating treatment or coating installations, which are operated under vacuum up to the performance limit of the vacuum motor pump sets and in which different treatments are carried out in individual treatment stations on so-called substrates, include, as a rule, the following assemblages:
a) at least one vacuum chamber
b) at least one evacuation or pumping system,
c) treatment stations accessible from the vacuum chamber with treatment sources,
d) optionally inner interlock valves at the entrance of the treatment stations,
e) supply facilities for the treatment sources (current and/or gas sources),
f) at least one interlock system with interlock valves for the transfer of the substrates in and out of the vacuum chamber through the interlock,
g) transport systems for the two- or multi-dimensional transport of the substrates,
h) substrate holders or carriers in cooperation with the transport systems, and
i) optionally superposed sets of machinery for the purpose of providing and/or removing the substrates in front of the interlock system of the installation.

To the extent installations with rotary and optionally radial transport paths are involved and treatment stations or chambers connected to at least one, at least substantially rotationally symmetric, main vacuum chamber, such installations are also referred to as “cluster installations”.

In the treatment processes are employed preheating (outgassing) and cooling of the substrates, vacuum vapor deposition, cathode sputtering, plasma treatment (for example incandescence for cleaning and adhesion promotion), PVD, CVD, and PCVD processes. For these processes numerous process parameters and device components are known. “P” denotes here “physical”, “C” chemical, “V” “vacuum” and “D” “deposition”. Some of these processes, for which the designations have become internationally established usage, can be completed reactively (with the supply of reaction gases or gas mixtures) or nonreactively (in the presence of inert gases). Added to these are etching processes for surface treatment including generation of specific “background [surface] pattern” and contact lines on the substrates. Depending on the requirements made of the end products, all of these process steps and device components are also appropriate for the subject matter of the invention.

In their historical development the continuous “cluster installations” were initially applied in the case of relatively small substrates such as disks, chips, data stores and wafers. However, the further development in reference to larger substrates, such as window panes and displays, encountered considerable problems, such as for example the dimensions of the installation, the space requirement for handling the substrates and optionally the substrate holders, for example raising substrates supplied in the horizontal position into a substantially perpendicular position, the hazard of elastic deformation, breakage and/or mechanical damage of the substrates and/or their coatings and contamination, especially through the accumulation of coatings on components continuously or temporarily in the installations, and spalling of these contaminations due to different process parameters, especially through temperature changes or mechanical effects.

For example, according to EP 0 136 562 B1, which will be discussed later, each substrate is supplied to an interlock system lying horizontally; in it is first raised upwardly by means of a lifting device and subsequently swiveled with a pivot device into a perpendicular position, in which it is secured on a substrate holder. During the transport out in a second interlock system, the sequence of these steps is subsequently reversed. In the case of large-area rectangular substrates this would lead to considerable space problems, large interlock and chamber volumes as well as long evacuation times and/or high evacuation performances of the vacuum pumps.

EP 0 136 562 B1 disclosed forming in a continuous cathode sputtering installation for small circular disk-form substrates such as disks, semiconductors and wafers, a vacuum chamber of two pot-form chambers, namely of a pentagonal outer chamber and a concentric cylindrical inner chamber, both of which are connected with one another fixedly and vacuum-tight by an annular upper cover. The bottoms have a small vertical distance from one another. The outer chamber is provided on the circumference equidistantly with an interlock installation and four chamber-form treatment stations. Such installations are also generally referred to as “cluster installations.

Between outer and inner chamber is rotatably disposed a further polygonal pot, on whose body five substrate holders are disposed by means of leaf springs, which in the operating position close the interlock installation as well as the processing chambers by means of seals and a valve function. The substrate holder pot also has a bottom disposed between the bottoms of outer and inner chamber. The radial movements of the substrate holders, which remain continuously in the vacuum chamber, are generated synchronously through a central cone and five slide rods, which are guided in the body of the inner chamber and through its wall at approximately half its height and which, consequently, cannot take part in the rotation. The drive unit with its cone is also stationary.

The substrate holder pot is rotated stepwise by a further drive unit. In order to be able to rotate the substrate holder pot within the vacuum chamber from station to station, said slide rods must be cyclically retracted from their circular or cylindrical movement path of the substrate holder pot and be advanced again. Since during the rotation of the substrate holders from station to station the openings of the treatment stations are made clear, coating material escapes at half its height into the space between outer and inner chamber and there condenses on the surfaces, thus also on the ends of the slide rods, its guides and on the leaf springs on the substrate holder pot. The layer thickness of these condensates, which increases from operating cycle to operating cycle, from time to time becomes spalled off in the form of particles and leads to contaminations, and specifically also on the surface of the rotatingly guided substrates, which thereby become unusable and consequently represent expensive rejects. Especially damaging are the peeling processes of the condensates at the inner ends of the slide rods.

It is asserted that in this structuring and operating manner the contaminations of the substrates through spalled off particles coming from above of collected layer material are said to be avoided; however, this applies at best to an absolutely perpendicular position of the substrate surfaces on the entire transport path within the vacuum chamber. But this presupposes the securement of the relatively small substrates on their holders.

Through EP 0 665 193 B1 and DE 695 04 716 T2 it is known in a cluster installation for the purpose of the delimiting placement areas and chamber volumes to transport through an interlock substrates comprised of glass for large-area flat and rectangular or square displays with dimensions of 450 mm×550 mm and greater in continuously perpendicular position by means of one substrate holder each from the environment into a system of vacuum chambers and to transport them out again to the environment by means of the same substrate holder together with it. Between a central buffer chamber and the individual treatment chambers valve gates are disposed in each instance. In the buffer chamber is disposed concentrically and with vertical axis a rotary table, with which the substrates with their holders and with their main planes, thus nearly radially, oriented toward the particular treatment chamber and from this position are moved into the treatment chambers and retracted again. However, the rotary table does not have substrate holders of its own. For transporting the substrate holders, in each treatment chamber and on the rotary table, separate from each other and driven separately, conveying facilities with rollers are disposed for the substrate holders. The constructional expenditures and the driving and control facilities are considerable; in particular, on the rotary table several conveying facilities with rollers can also be disposed independently of one another. If a circle is drawn about the rotational axis of the rotary table, which also includes the radially projecting treatment chambers, a large requirement of placement area for the complete device results, especially also because the substrates are held “standing on one of their points” in the large-area substrate holders such that the diagonal dimensions of the substrates determine the diameter of said circle. The problem is thereby not eliminated of repeated transport of all substrate holders between the environment and the interior of the installation with the consequence of the spalling off of accumulated layers due to temperature changes in the installation.

DE 200 22 564 U1 discloses transferring carriers with substrates for coating purposes through a first interlock into a vacuum, guiding them continuously on a circular or partially circular path and, lastly, after the coating transferring them out again through a second interlock. Radial movements or movements with a radial component of the carriers within the vacuum chamber and opposite to the coating stations, deviating from the circular path, are not provided. The return transport of the empty carriers from the discharging interlock to the charging interlock outside of the vacuum chamber should take place on the shortest possible path or as rapidly as possible in order to limit the spalling of the layers accumulating on the carriers within the vacuum chamber due to temperature fluctuations.

DE 102 05 167 C1 discloses connecting in an in-line vacuum coating installation two buffer chambers with rotatable exchange units for carriers with substrates with one another through two linear transport paths of variable length, in order to be able to change the number of coating stations. The carriers can be transported in perpendicular or minimally inclined positions. The one transport path is provided for discontinuous transport and has at both ends, adjoining onto the buffer chambers, one interlock chamber each with two valves, and in front of it or following it a loading and an unloading station for the carriers. The other transport path is provided for the continuous transport and has at both ends, adjoining the buffer chambers via valves, one transfer region each for the carriers, each with the substrates. Means for a carrier movement transversely to the direction of transport within the installation are not provided and specifically neither on the linear transport paths nor in the buffer chambers, nor in the transfer regions. The buffer chambers are only provided with means for heating and cooling.

It is known from US 2002/0078892 A1 to transport large-area rectangular substrates with dimensions of 1 m×1.2 m and greater for LCD displays pairwise and perpendicularly parallel to one another or at the upper edges inclined toward one another at an acute angle on different transport paths from atmosphere to atmosphere through vacuum installations—including cluster installations. For this purpose serve substrate holders with a horizontal plate, on the upper side of which, disposed mirror symmetrically, two frames, open at the inside, are disposed as substrate holders and at whose under side along the plane of symmetry a bracket plate with bilateral toothed bars is disposed, by means of which the substrate holders can be driven by series of pinions driven by toothed belts, in different and changing directions.

Again, as the central part of the transport device serves here also a rotationally symmetric throughpassage or buffer chamber with a rotary table, on whose underside such a pinion drive is disposed with six pinions and a motor for guidance, change of displacement direction and for the radial displacement of the substrate holders. On the circumference of the buffer chamber are disposed, separated via gate valves, an interlock system and at least three treatment chambers for diverse vacuum processes. The substrate holders are moved in the radial longitudinal direction into the treatment chambers, which, consequently, must have the corresponding radial dimensions, such that an imaginary circle about the entire installation has a large diameter, leading to a correspondingly large placement area. The longitudinal displacement and corresponding drive units in the treatment chambers are also required for the reason that such treatment chambers can also be arranged serially in radial directions.

As prior art is described in US 2002/0078892 A1 a rotary table with a transfer robot and two grippers, which are actuated in the radial direction via articulation members in the manner of a scissors articulation. However, the patent expressly states that herein the substrates are held on the entire transport path eccentrically and in the horizontal position and that with increasing dimensions of the substrates for displays, for example, for wall display screens, this leads to space and volume problems as well as longer pumping times and to flexure or breaking under their own weight of the substrates which are only 0.7 mm thick. An enlargement of the horizontal dimensions of the substrates leads to the twofold value of the diameter enlargement, for example beyond 2 m, which is tied to additional enlargements of the interlock valves and to problems of mass during acceleration and delay and to tolerance problems.

US 2002/0078892 A1 further specifies that the bracket plate of the rotary table can be raised from a guidance rail by means of a magnetic lifting drive unit in order to avoid dust development through abrasion. However, not addressed is the problem of avoidance of dust formation through the spalling off of layer material cumulatively collected on the substrate holders due to the transport from atmosphere to atmosphere and heating within the vacuum chambers, as well as through abrasion from the pinion drive units. A further significant disadvantage of the known configuration is, however, that with the number of the treatment chambers connected to the central or buffer chamber, the number grows of transport mechanisms in the interior of the chamber, which must be compatible with the transport mechanism of the rotary table in the buffer chamber in order for the transfer into and out of the treatment chambers to be possible at all.

In conjunction with the above prior art it was shown that, due to the continual enlargement of the substrate dimensions and the decrease of the inherent shape stability and nondeformability due to the decrease of the substrate thickness, with advancing development new problems were generated, which have led to highly complex and expensive constructional principles and complicated operating sequences, and yet, nevertheless, the problem of placement area and of contamination of the substrates through particles of accumulated layers on installation components could not be successfully solved to satisfaction.

The invention therefore addresses the problem of specifying constructional principles and operation sequences leading to a further decrease of the placement area, the chamber volumes, the evacuation times and to a further simplification of the “handling” of the substrates outside and within the vacuum chamber and yet especially to a marked reduction of the contamination hazard of the substrates through particles of spalled off layer packets.

The solution of the posed problem is achieved according to the invention through the characteristics in the characterizing clause of patent claim 1, namely thereby that the substrate holders are connected in their lower regions via pivotable connecting rod configurations with the driving mechanism and that at least the lower pivot bearings of the connecting rod configurations are disposed below a horizontal center line of the height of the bearing surface of the substrate holders.

Through this solution the posed overall problem is fully solved to satisfaction, in particular constructional principles and operation sequences are specified, which lead to a further decrease of the placement area, the chamber volumes, the evacuation times and to a further simplification of the “handling” of the substrates outside and within the vacuum chamber and yet lead especially to a marked decrease of the contamination hazard of the substrates through particles of spalled off layer packets. The constructional expenditure and the number of rejects are decreased and the product quality is considerably enhanced.

In the course of further implementations of the invention it is especially advantageous if, either singly or in combination:
all pivot bearings of the pivotable connecting rod configurations are disposed below the horizontal center line of the height of the bearing surface of the substrate holders,
the driving mechanism for each substrate holder comprises [extension] arms disposed pairwise, on each of which a parallelogram connecting rod configuration is suspended,
the lower pivot bearings of the parallelogram connecting rod configurations are each disposed on a U-form stirrup, whose outwardly directed shanks are connected to a crosstie bar forming the lower termination of the particular substrate holder,
the driving mechanism comprises a rotary plate, on which is set up a group of trapezoidal connecting rod configurations for each substrate holder,
the driving mechanisms is a rotary and lifting drive with a concentric shaft, through whose vertical movement the trapezoidal connecting rod configurations can be made to act with radial movements onto the substrate holder,
the vacuum chamber
a) comprises a pot-form rotationally symmetrical and stationary inner chamber component with a vertical axis and a first bottom,
b) comprises an outer chamber component encompassing the inner chamber component at an offset, between which an annular space for the rotation of the substrate holder is disposed, the outer chamber component being provided with several openings disposed at uniform angular distance and treatment chambers connected thereon, and comprises a further bottom, which is disposed stationarily and at a spacing beneath the first bottom,
c) for the synchronous radial movement of the substrate holders relative to the openings of the treatment chambers comprises at least one connecting rod configuration which is disposed rotatably about the axis between the first bottom and the second bottom, and lastly,
d) comprises a series of interlocks with a transfer chamber for the successive charging of the installation with framelessly guided substrates,
the linear aligned interlock series is disposed tangentially oriented toward the vacuum chamber and comprises a charging interlock, a transfer chamber and a discharging interlock with interconnected vacuum valves, the interlock series defining a linear transport path of the substrates before and after the vacuum treatment,
the substrate holders rotatable about the perpendicular axis are disposed sloped upwardly at an angle between 1 and 20 degrees with respect to the axis, in particular if the substrate holders rotatable about the perpendicular axis are disposed at a slope with respect to the axis upwardly at an angle between 3 and 15 degrees,
if for the frameless guidance of the substrate in the interlock chambers stationary substrate holders are located, which are disposed at the same angle relative to the vertical as the rotatable substrate holders (13),
the substrate holders comprise at their lower ends rollers for receiving and transferring the substrates and thereabove openings for the escape of gases for the formation of gas cushions for the frictionless transport of the substrates during their relative movement to the particular substrate holder,
the openings of the treatment chambers have edges with respect to their opposite rotatable substrate holders, which edges are in a plane parallel to that of the substrate holders,
the openings of the treatment chambers are provided with screens for masking the substrates during the treatment,
the connecting rod configurations for the advance of the rotatable substrate holders have exclusively articulations with which the substrate holders are movable without the occurrence of linear sliding friction,
the shortest and upper members of the trapezoidal connecting rod configurations have in their center further articulations, and two serially connected trapezoidal connecting rod configurations are connected by means of distance connecting rods, such that the serially connected trapezoidal connecting rod configurations in each instance assume identical angular positions,
the driving mechanism for the shaft is disposed in the inner chamber component which is open to to the atmosphere,
the upper members of the trapezoidal connecting rod configurations have fixedly situated further connecting rods, whose lower ends are connected via articulations with extension arms, at whose outer ends the substrate holders are secured,
the upper members and their connecting rods have the form of a “T”, in particular if
on the shaft a bearing flange is disposed, which acts via connecting rods onto angle levers pivoted on the rotary plate and whose one shank is a portion of the particular innermost trapezoidal connecting rod configurations and through which a swiveling of the trapezoidal connecting rod configurations can be brought about.

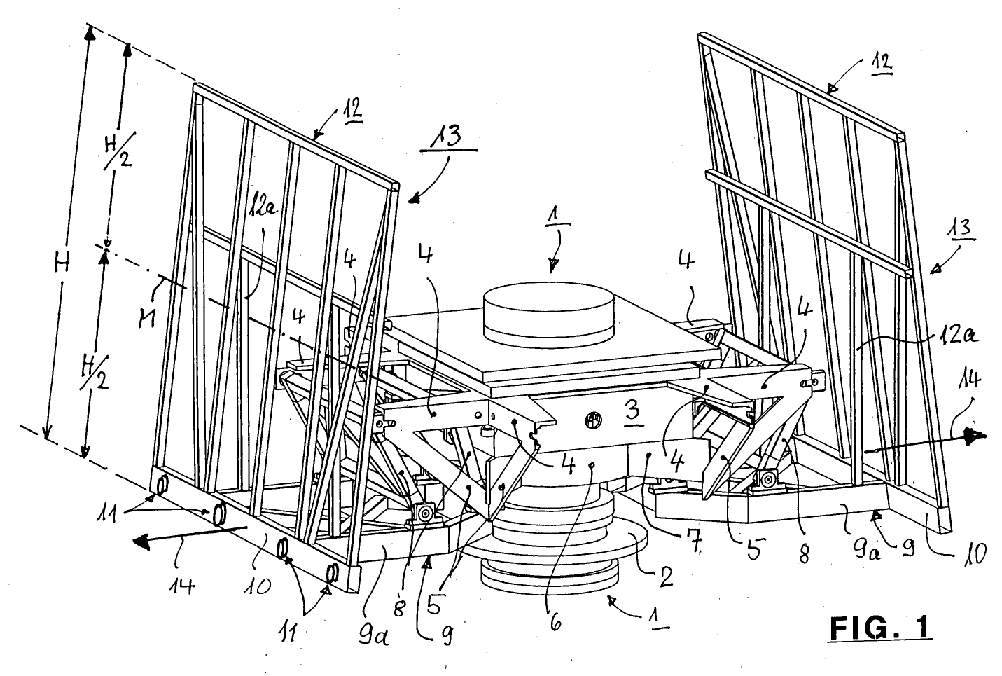

In the following two embodiment examples of the subject matter of the invention and their operational function will be explained in further detail in conjunction with FIGS. 1 to 10. In the drawing depict:

FIG. 1 perspective representation of the inner driving mechanism with two substrate carriers in the radially retracted position,

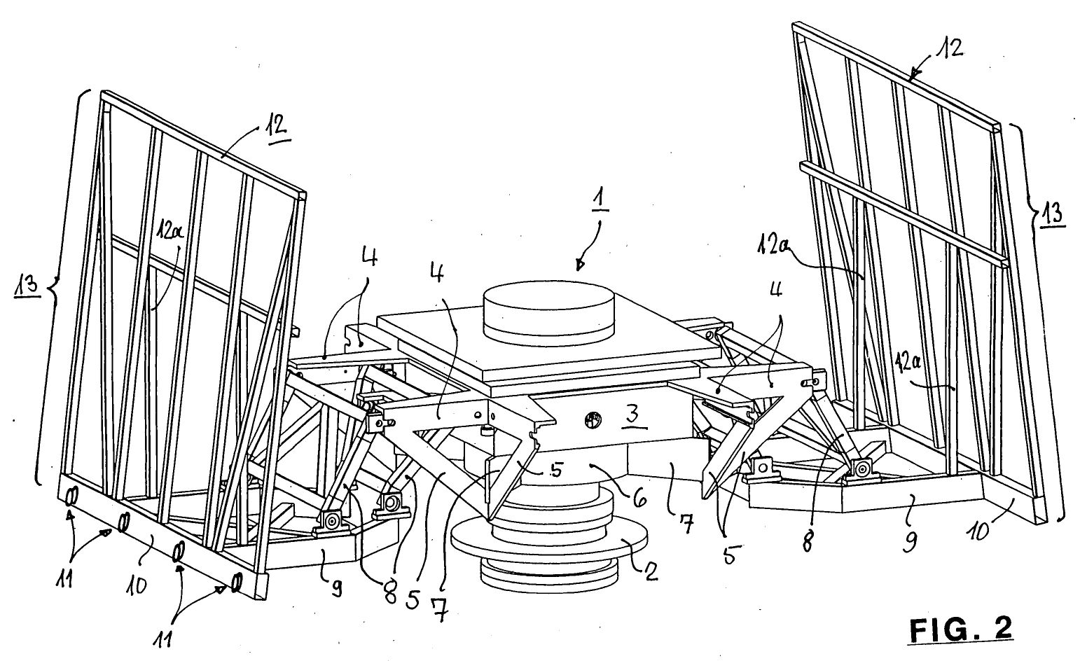

FIG. 2 perspective representation of the inner driving mechanism analogous to FIG. 1, however with two substrate carriers in the radially extended position,

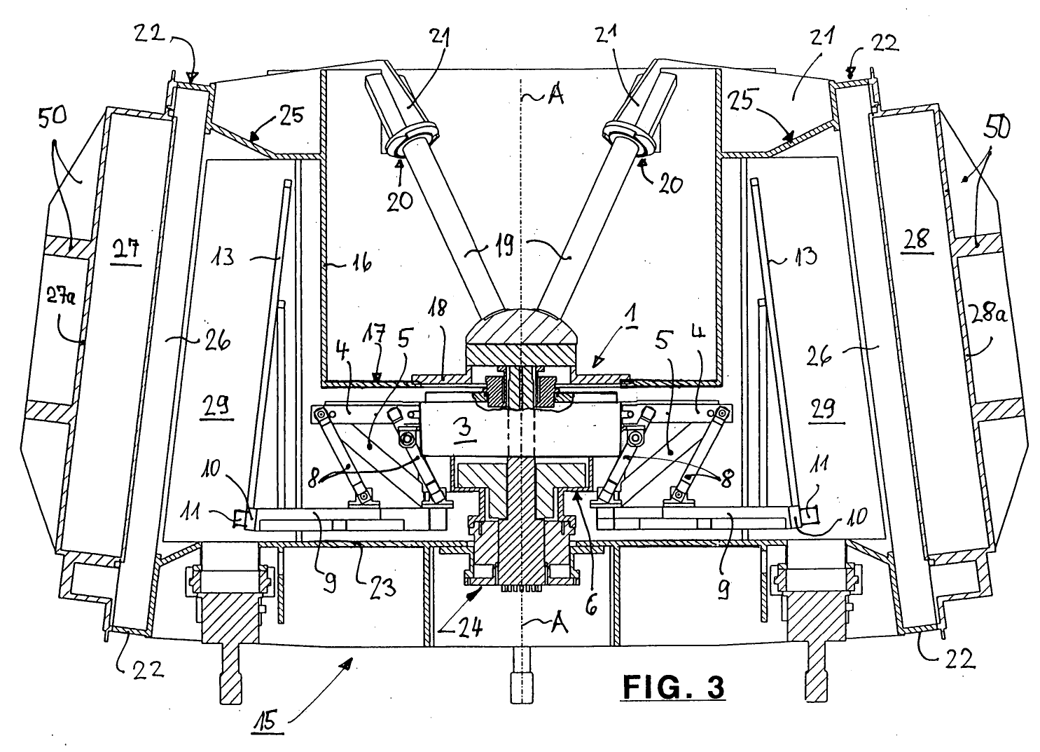

FIG. 3 a partial vertical radial section through a vacuum installation with a driving mechanism in the position according to FIG. 1,

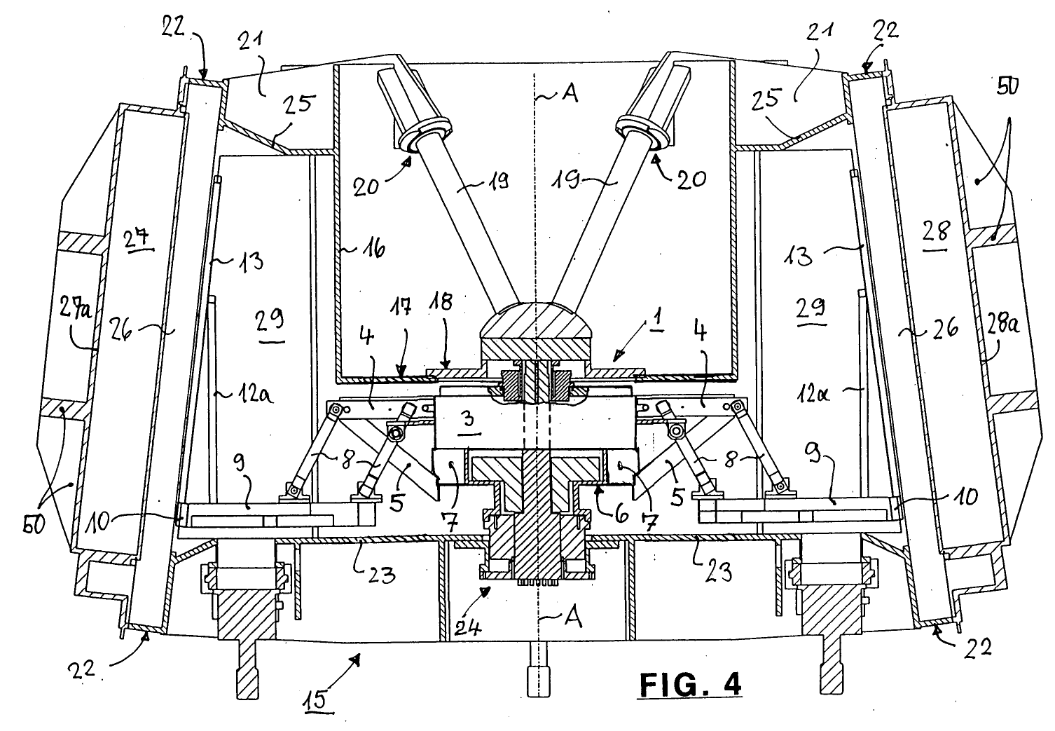

FIG. 4 a partial vertical radial section through a vacuum installation with a driving mechanism in the position according to FIG. 2,

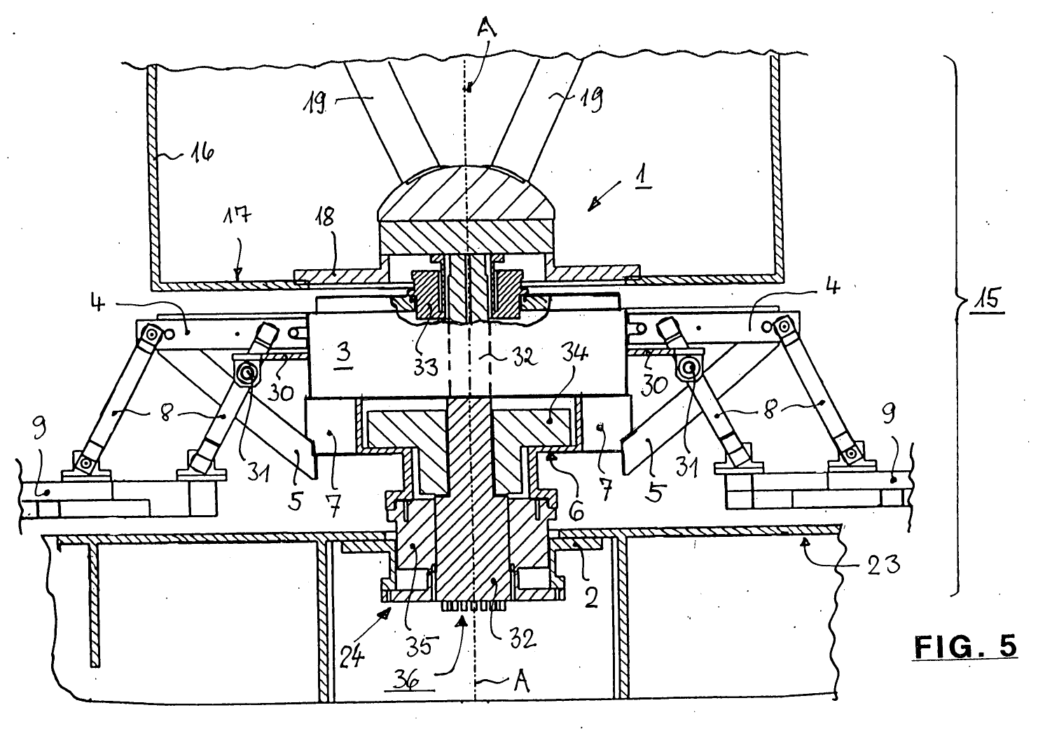

FIG. 5 an enlarged cutaway portion from the driving mechanism according to FIG. 4,

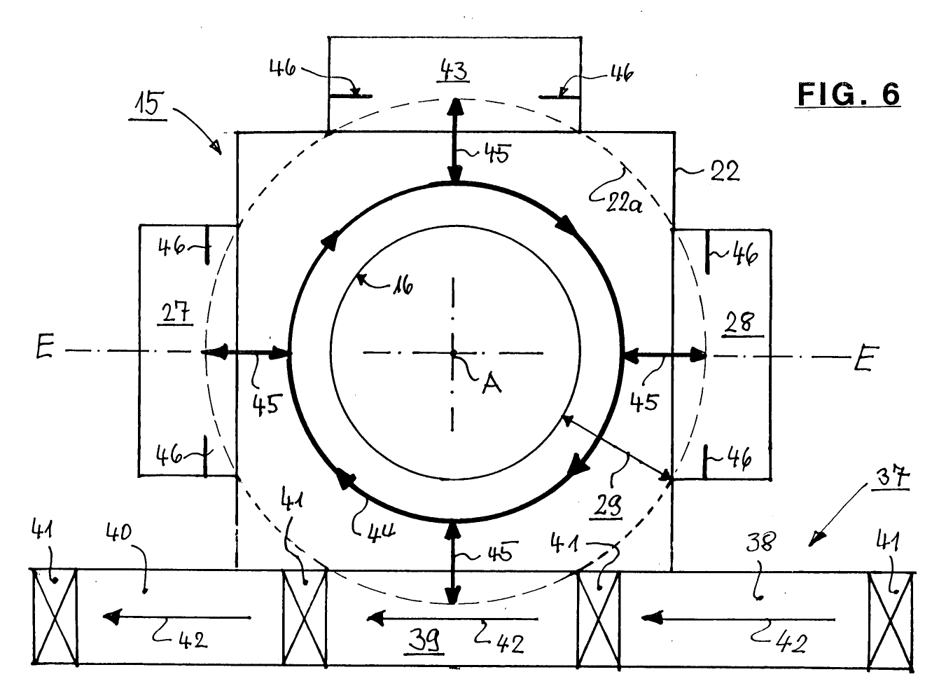

FIG. 6 schematic representation of the superimposed movement sequences in the circumferential direction and in the radial directions,

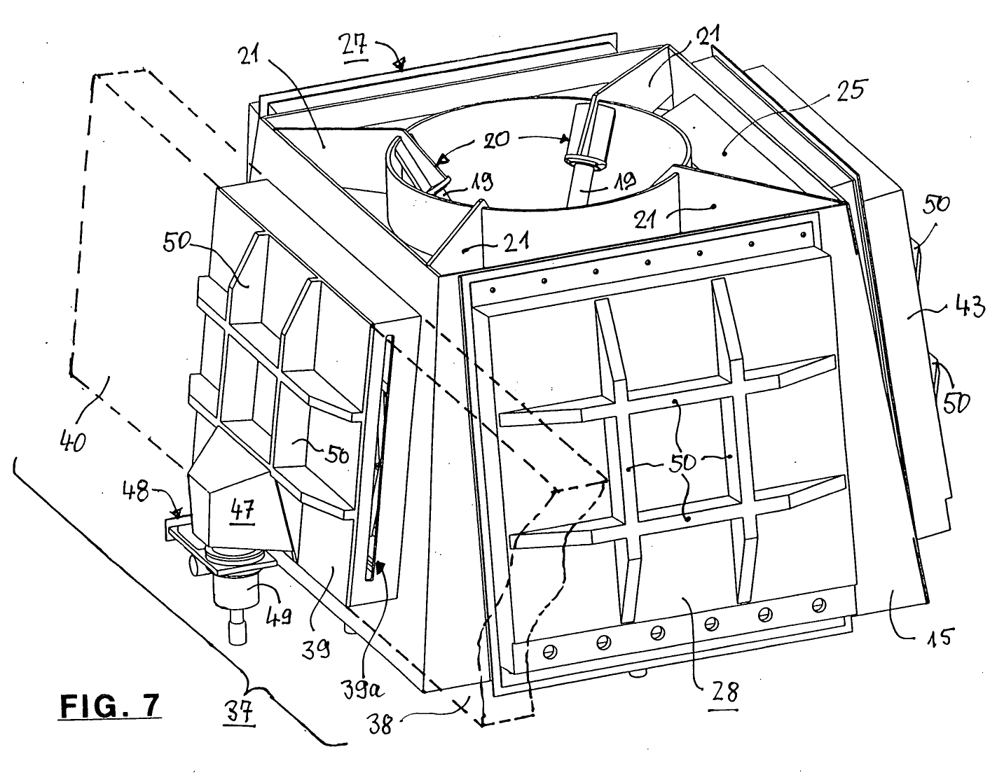

FIG. 7 perspective exterior view of an entire installation with the means according to FIGS. 1 to 6,

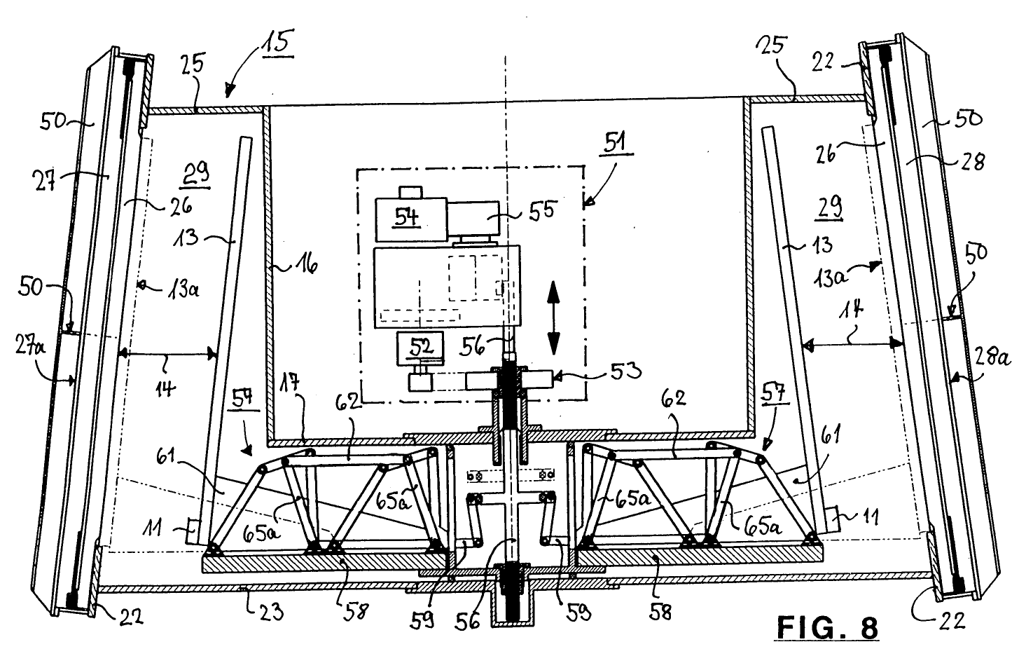

FIG. 8 variant of the subject matter according to FIGS. 1 to 7 with retracted substrate holders analogous to FIG. 3,

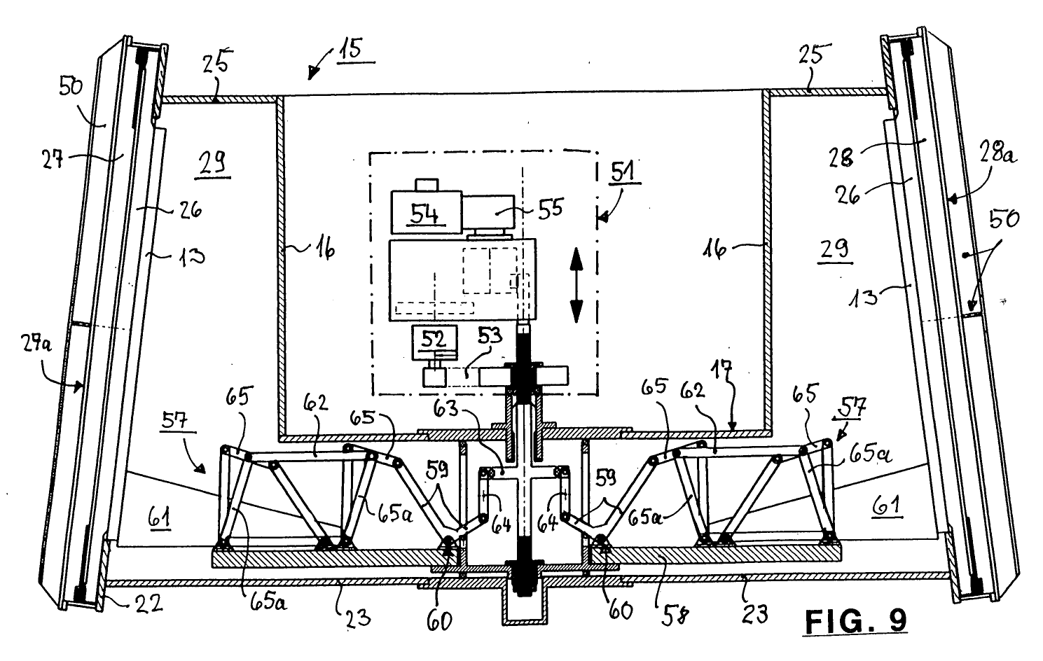

FIG. 9 the subject matter of FIG. 8 with extended substrate holders analogous to FIG. 4, and

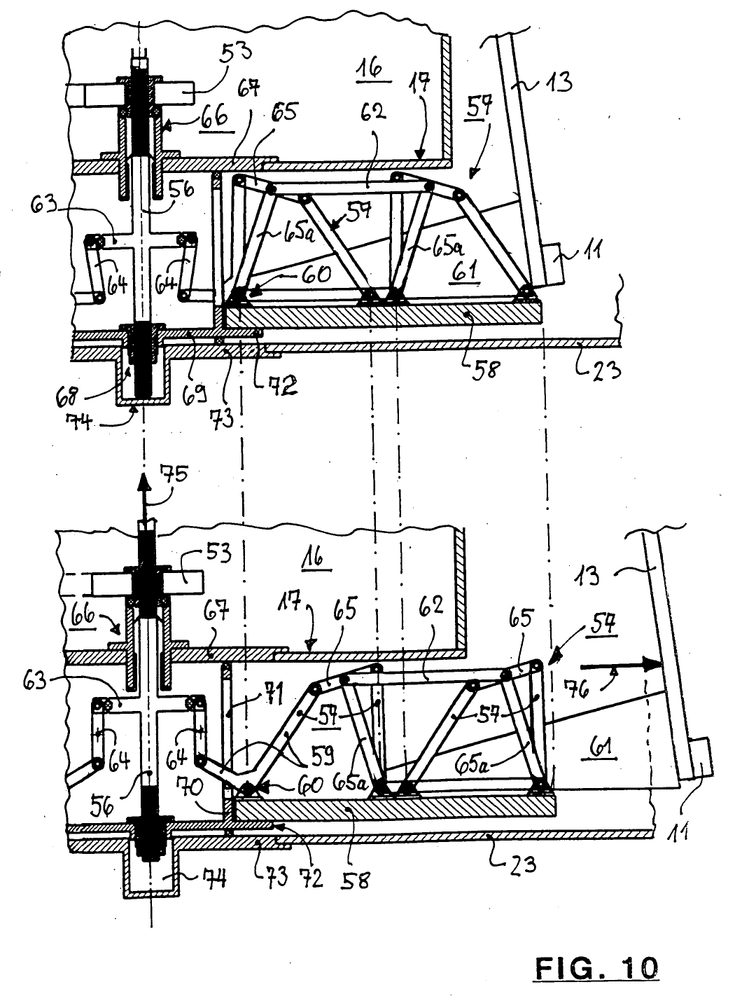

FIG. 10 a comparison of cutaway portions from FIGS. 8 and 9.

In FIGS. 1 and 2 a central driving mechanism 1 is shown with perpendicular axis and coaxial mounting flange 2 for the securement on a (not shown here) lower bottom of the vacuum chamber. This driving mechanism 1 bears in its upper region a rotatable chamber 3 with square outline at whose corners overall are fastened eight extension arms 4, which are braced on a cylindrical substructure 6 of the chamber 3 via oblique struts 5 and specifically in each instance joined together pairwise via four radially projecting extension arms 7 (see FIG. 2).

On the extension arms 4, which pairwise extend parallel toward one another and form a right-angled cross, are downwardly suspended overall eight parallelogram connecting rod configurations 8 via upper fixed pivot bearings. The lower ends of the parallelogram connecting rod configurations 8 are pivotably supported on horizontal U-form stirrups 9 with shanks 9a pairwise parallel to one another, whose outwardly directed ends are connected by one crosstie bar 10 each. Each of the crosstie bars 10 carries at least two projecting rollers 11, which serve as supports for substrates, not shown here, and are optionally drivable and/or arrestable. Each of the crosstie bars 10 supports toward the top a frame structure 12, directed obliquely and upwardly at an angle between 3 and 15 degrees with respect to the vertical with longitudinal and transverse struts in the manner of a framework, which is braced via vertical uprights 12a on the particular stirrup 9.

The outsides of the crosstie bars 10 and of the frame structure 12 are disposed in a common plane, whose outline corresponds at least substantially to the outline of the particular substrate. These parts thereby form a dimensionally stable substrate holder 13. In the direction of their said planes these [holders] have a height “H” and define in their midpoints (H/2) a horizontal virtual center line “M”, below which all connecting rod configurations and their pivot articulations are disposed.

The two substrate holders 13 shown are thereby movable oppositely in the direction of arrows 14 and essentially radially toward one another. It must be emphasized that only two of the substrate holders 13 are shown. The two remaining substrate holders disposed in front of and behind the driving mechanism 1 are not depicted for the sake of clarity. They are also radially movable in opposite directions and specifically at right angles to the two arrows 14.

The frame structures 12 are perforated at numerous sites and connected to a (not shown) gas source, such that the substrates can be loaded in the charging position in the manner of an “air cushion vehicle” free of friction and preserving form onto the particular substrate holder 13 guided by the rollers 11. The gas supply is subsequently interrupted in order for the gas atmospheres in the individual treatment chambers not to be impaired.

FIGS. 3 and 4 show the rotation system according to FIGS. 1 and 2 integrated into a vacuum chamber 15 with a vertical axis A-A. The vacuum chamber 15 is comprised of an inner pot-form chamber component 16 with a bottom 17, into which is set vacuum-tight the upper end region of the driving mechanism 1 by means of a flange 18. The vertical bracing takes place via four anchor struts 19 whose effective length is variable via adjusting elements 20. Of these only the two adjusting elements 20 located behind the vertical section plane (E-E in FIG. 6) are shown, which are suspended on radial gusset plates 21.

The vacuum chamber 15 comprises furthermore an outer chamber component 22 in the form of a square truncated pyramid with a bottom 23, through which is guided under vacuum seal the lower end region 24 of the driving mechanism 1. The inner and the outer chamber component 16 or 22 are connected vacuum-tight through a roof 25. The walls of the outer chamber component 22 are provided with four equidistantly distributed rectangular openings 26, of which here also only two diametrically opposite openings 26 are evident. Onto the openings 26 are set treatment chambers 27 and 28, which can be equipped with (not shown) facilities for the most diverse vacuum processes. The outer walls 27a and 28a of the treatment chambers 27 and 28 are provided with ribbings 50 for absorbing the forces of atmospheric pressure (esp. FIG. 7).

Between the horizontal bottoms 17 and 23 are located the essential rotatable parts of driving mechanism 1, which will be explained in further detail in conjunction with FIG. 5. Into the annular space 29 between the inner and the outer chamber components 16 or 22 project from below upwardly the rotatable substrate holders 13 displaceable with radial components. Slide leadthroughs through the cylindrical wall of the inner chamber component 16 are not provided. The displacement of the substrate holders 13 from the position according to FIG. 3 into that according to FIG. 4 takes place rather through the already described parallelogram connecting rod configurations 8, in which the spatial position of the pivot bearings is already evident from the definition “parallelogram connecting rod configurations”. Only that much is stated that the lowest points of the lower pivot bearings are disposed below the corresponding upper pivot bearings of the particular identical connecting rod. Consequently, a symmetric swiveling about a center position is carried out. Through the adequate dimensioning of the length of the connecting rods at a given dimensioning of the pivot angle or of the radial movement component it can be attained that the vertical movement component becomes minimal. In contrast to slide leadthroughs, such pivot bearings generate virtually no abrasion and also no dust of coating material which could affect the layer qualities on the substrates. Added to this is that the engagement of the U-form stirrups 9 on the substrate holders 13 takes place at their lower edge and not in the substrate center as is the case with the subject matter of EP 0 136 562 B1. The lower pivot bearings of the already described parallelogram connecting rod configurations 8 are located only at the smallest possible distance above the top sides of stirrups 9 and on the backsides of the substrate holders 13, such that for this reason also an abrasion cannot reach the outsides of the substrates.

FIG. 5 depicts an enlarged cutaway portion from the driving mechanism 1 in its position according to FIG. 4. The previously used reference symbols are used and will continue to be used. In the rotatable chamber 3 are disposed a drive motor for the stepwise rotational movement as well as horizontal control rods 30 for the cyclic movement of the already described parallelogram connecting rod configurations 8, the control rods 30, guided and driven in the interior of chamber 3, projecting with their outer ends from chamber 3 and engaging the particular inner connecting rods via pivot bearings 31.

The driving mechanism 1 comprises a coaxial shaft 32 passing through bottoms 17 and 23, which shaft is guided by means of a first vacuum-tight rotational leadthrough 33 through the upper bottom 17, and by means of a second vacuum-tight rotational leadthrough 34 and through a radial bearing 35 through the lower bottom 23. A group of connection fittings 36 serves for supplying treatment media and, if required, also for the current feed.

FIG. 6 depicts a schematic representation of the superimposed movement sequences in the circumferential direction and in the radial direction. Parallel to the outer chamber component 22, which can also be implemented in the manner of a truncated cone according to the dashed circle 22a, extends parallel to a tangent on the vacuum chamber 15 a series of interlocks 37 comprised of a charging interlock 38, a transfer chamber 39 and a discharging interlock 40. The interlock series 37 includes vacuum valves 41 of known structural type. Line E-E represents the vertical section plane of FIGS. 3 and 4.

The linear stepwise transport direction of the substrates in oblique position or guided in oblique position without substrate holder through the interlock series 37 is indicated by the series of arrows 42. Opposite to the transfer chamber 39 is a further treatment chamber 43. In the interior of the annular space 29 the movement sequences are indicated by thick arrow lines. Starting at the transfer chamber 39, the stepwise rotational movement takes place by 90 degrees in each instance along the closed arrow line 44. At each of the four stopping points directly in front of the transfer chamber 39 and the treatment chambers 27, 43 and 28 the advance and retraction of the substrates are indicated by radial double arrows 45. The advance of the substrates takes place up to immediately in front of shielding frame-form screens 46 disposed in the opening regions of the treatment chambers 27, 43 and 28. However, a sealing effect between the substrates and these screens 46 is not required for the reason alone that the extremely thin substrates cannot or must not perform a [sealing] contribution. As soon as the rearward movements of the substrate holders are completed, these are rotated by 90 degrees in front of the particular next treatment chamber, and at the end of the treatment, in front of the transfer chamber 39 for further transport into the discharging interlock 40.

FIG. 7 shows a perspective exterior view of an entire installation with the means and the reference symbols according to FIGS. 1 to 6. On both sides of the transfer chamber 39 the charging interlock 38 and the discharging interlock 40 are indicated in dashed lines. Of the transfer chamber 39 is shown the oblique entrance slot 39a and also a pumping fitting 47 connected thereon with a gate valve 48 and a cryopump 49. Clearly evident are the ribbings 50 of the transfer chamber 39 and of the treatment chamber 28 against atmospheric pressure.

The highly compact implementation of the installation saving space and volume is especially evident in FIGS. 6 and 7, especially the fact that the substrate holders do not have to be transported out to the atmosphere through an interlock. In all cases are also disposed in the interlock chambers 38 and 40 perforated substrate holders with compressed gas supply over the entire substrate surface and rollers at the lower end, such that the substrates can be slid free of friction via gas cushions onto the substrate holders and again be slid off. For the evacuation and during standstill of the substrates on their holders, the gas supplies are temporarily switched off. This applies also to the time interval in which the substrates on their substrate holders are located in vacuum chamber 15. This applies also to the following embodiment example.

FIGS. 8 and 9 depict a variant of the subject matter according to FIGS. 1 to 7 with the continued use of the previous reference symbols. Different is here the rotation and advance drive unit for the substrate holders 13. In the pot-form inner chamber component 16 with bottom 17 is here disposed a rotary and lifting drive unit 51 comprising a first motor 52 with step-down gearing 53 for generating a rotational movement and a second motor 54 with step-down gearing 55 for generating a lifting and lowering movement of a common shaft 56. Four double trapezoidal connecting rod configurations 57 are disposed on a rotary plate 58, which can be set stepwise into rotation through the shaft 56. The substrate holders 13 are shown in FIG. 8 with continuous lines in their retracted positions.

By lifting the shaft 56, which includes a bearing flange 63, via connecting rods 64 (FIG. 9) suspended thereon and nearly perpendicular, four angle levers 59 are swiveled outwardly about their fixed bearing 60, whereby the trapezoidal connecting rod configurations 57 are swiveled at their upper ends outwardly as is shown in FIG. 9. The uppermost and shortest members 65 of the trapezoidal connecting rod configurations 57 are implemented in the form of a T and are provided in their midpoints with further articulations, two serially connected trapezoidal connecting rod configurations 57 being connected by horizontal distance connecting rods 62, such that each of the serially connected trapezoidal connecting rod configurations 57 assumes the same angular positions with respect to the rotary plate 58. The T-form implementation of the members 65 takes place through a connection with further connecting rods 65a, joined torsionally tight, whose lower ends are connected via pairs of not especially emphasized pivot bearings with the horizontal lower edges of wedge-form extension arms 61, disposed at the lower ends of substrate holders 13. This movement forced by the angle levers 59 is tracked synchronously by all other trapezoidal connecting rod configurations 57.

Thereby the extension arms 61 are pulled in and the substrate holders 13 secured thereon standing in oblique position. The layout of the trapezoidal connecting rod configurations 57 is made such that a vertical component of the radial movement is minimal. At the end of the radial movement the substrate holders 13 assume the positions 13a, indicated in FIG. 8 in dot-dash lines, opposite the treatment chambers 27 and 28. The same applies to the positions of the substrate holders 13 opposite the further treatment chamber and the transfer chamber, which have here been omitted for the sake of clarity. The radially outer end position of the substrate holders 13 is shown in FIG. 9 by means of continuous lines.

In conjunction with FIG. 10, FIGS. 8 and 9 are compared with one another utilizing the previous reference symbols and their continuation. Shaft 56 is guided through the bottom 17 of the inner chamber component 16 by means of a a combination 66 of an upper rotary bearing and a vacuum leadthrough by means of a torsion-tight circular disk-form support plate 67. The lower end of shaft 56 is axially displaceable in a lower rotary bearing 68, which, in turn, is supported in a further rotary disk 69, which in the upward direction bears a cylindrical riser 70 with penetrations 71 and a radial flange 72, onto which is set the rotary plate 58 with the trapezoidal connecting rod configurations 57. The sealing toward the downward direction takes place through a stationary support plate 73, which is set vacuum-tight into the bottom 23 of the outer chamber component 22 and beneath the end of the shaft 56 is provided with a pot-form prolongation 74 for the lowering of the shaft 56.

It is clearly evident that through the lifting of the shaft 56 in the direction of arrow 75 the entire trapezoidal connecting rod configurations 57, and therewith the substrate holders 13, are synchronously displaceable via the angle levers 59 and the distance connecting rods 62 in the direction of arrow 76, since the extension arms 61 are articulatedly pivoted on the lower ends of the connecting rods 65a fixedly connected with the members 65.

### List of Reference Symbols

1 Driving mechanism
2 Mounting flange
3 Chamber
4 Extension arm
5 Oblique struts
6 Substructure
7 Extension arm
8 Parallelogram connecting rod configurations
9 Stirrup
10 Crosstie bar
11 Rollers
12 Frame structure
12a Uprights
13 Substrate holder
13a Positions
14 Arrows
15 Vacuum chamber
16 Chamber component
17 Bottom
18 Flange
19 Anchor struts
20 Adjusting elements
21 Gusset plates
22 Chamber component
22a Circle
23 Bottom
24 End region
25 Roof
26 Openings
27 Treatment chamber
27a Outer wall
28 Treatment chamber
28a Outer wall
29 Space
30 Control rods
31 Pivot bearing
32 Shaft
33 Rotational leadthrough
34 Rotational leadthrough
36 Radial bearing
36 Connection fittings
37 Interlock series
38 Charging interlock
39 Transfer chamber
39a Entrance slot
40 Discharging interlock
41 Vacuum valves
42 Arrows
43 Treatment chamber
44 Arrow line
45 Double arrows
46 Screens
47 Pump fitting
48 Gate valve
49 Cryopump
50 Ribbings
51 Rotary and lifting drive
52 Motor
53 Step-down gearing
54 Motor
55 Step-down gearing
56 Shaft
57 Trapezoidal connecting rod configurations
58 Rotary plate
59 Angle lever
60 Fixed bearing
61 Extension arm
62 Distance connecting rod
63 Bearing flange
64 Connecting rod
65 Members
65a Connecting rod
66 Combination
67 Support plate
68 Rotary bearing
69 Rotary disk
70 Riser
71 Penetrations
72 Flange
73 Support plate
74 Prolongation
75 Arrow
76 Arrow
A-A Axis
E-E Line/section plane
H Height
M Center line

1. Vacuum treatment installation for flat rectangular or square substrates in an at least substantially perpendicular position, comprising a vacuum chamber (15) with at least two treatment chambers (27, 28, 43) distributed on the circumference of the vacuum chamber (15) and open at the chamber side, a charging interlock (38), a discharging interlock (40) and a rotatable configuration of substrate holders (13) within the vacuum chamber (15) with a driving mechanism (1, 51) for the sequential rotation and the advance and retraction of the substrate holders (13) relative to the treatment chambers (27, 28, 43), characterized in that the substrate holders (13) in their lower regions are connected with the driving mechanism (1, 51) via connecting rod configurations (8, 57) and that at least the lower pivot bearings of the connecting rod configurations (8, 57) are disposed below a horizontal center line (M) of the height (H) of the bearing surface of the substrate holders (13).

2. Vacuum treatment installation as claimed in claim 1, characterized in that all pivot bearings of the connecting rod configurations (8, 57) are disposed below the horizontal center line (M) of the height (H) of the bearing surface of the substrate holders (13).

3. Vacuum treatment installation as claimed in claim 1, characterized in that the driving mechanism (1) for each substrate holder (13) has extension arms (4) disposed pairwise, on each of which is suspended a parallelogram connecting rod configuration (8).

4. Vacuum treatment installation as claimed in claim 3, characterized in that the lower pivot bearings of the parallelogram connecting rod configurations are each disposed on a U-form stirrup (9), whose outwardly directed shanks (9a) are connected with a crosstie bar (10), which forms the lower termination of the particular substrate holder (13).

5. Vacuum treatment installation as claimed in claims 1 and 2, characterized in that the driving mechanism (51) possesses a rotary plate (58), on which a group of trapezoidal connecting rod configurations (57) is set up for each substrate holder (13).

6. Vacuum treatment installation as claimed in claim 5, characterized in that the driving mechanism (51) is a rotary and lifting drive with a concentric shaft (56), through whose vertical movement the trapezoidal connecting rod configurations (57) is brought to act with radial movements onto the substrate holders (13).

7. Vacuum treatment installation as claimed in at least one of claims 1 to 6, characterized in that the vacuum chamber (15)
a) comprises a pot-form rotationally symmetric and stationary inner chamber component (16) with a vertical axis (A-A) and a first bottom (17),
b) comprises an outer chamber component (22) encompassing at an offset the inner chamber component (16), between which an annular space (29) for the rotation of the substrate holders (13) is disposed, the outer chamber component (22) being provided with several openings (26) disposed at the same angular distance and treatment chambers (27, 28, 43) connected thereon, and comprises a further bottom (23) disposed stationarily and at a spacing beneath the first bottom (17),
c) for the synchronous radial movement of the substrate holders (13) relative to the openings (26) of the treatment chambers (27, 28, 43) comprises at least one connecting rod configuration (8, 57), which is disposed rotatably about the axis (A-A) between the first bottom (17) and the second bottom (23), and lastly
d) comprises a series of interlocks (37) with a transfer chamber (39) for the successive charging of the installation with substrates guided free of frames.

8. Vacuum treatment installation as claimed in at least one of claims 1 to 7, characterized in that the linear aligned interlock series (37) is disposed tangentially oriented with respect to the vacuum chamber (15) and comprises a charging interlock (38), a transfer chamber (39) and a discharging interlock (40) with interconnected vacuum valves (41), the series of interlocks (37) defining a linear transport path of the substrates before and after the vacuum treatment.

9. Vacuum treatment installation as claimed in at least one of claims 1 to 8, characterized in that the substrate holders (13) rotatable about the perpendicular axis (A-A) are disposed sloped upwardly at an angle between 1 and 20 degrees with respect to the axis (A-A).

10. Vacuum treatment installation as claimed in claim 9, characterized in that the substrate holders (13) rotatable about the perpendicular axis (A-A) are disposed sloped upwardly at an angle between 3 and 15 degrees with respect to the axis (A-A).

11. Vacuum treatment installation as claimed in at least one of claims 1 to 10, characterized in that for the frame-less guidance of the substrates are disposed in the interlock chambers (38, 40) stationary substrate holders, which are disposed at the same angle with respect to the vertical as the rotatable substrate holders (13).

12. Vacuum treatment installation as claimed in at least one of claims 1 to 11, characterized in that the substrate holders (13) comprise at their lower ends rollers (11) for receiving and transferring the substrates and thereabove openings for the escape of gases for the formation of gas cushions for the frictionless transport of the substrates during their relative movement to the particular substrate holder (13).

13. Vacuum treatment installation as claimed in at least one of claims 1 to 12, characterized in that the openings (26) of the treatment chambers (27, 28, 43) with respect to the rotating substrate holders (13) opposing them have edges disposed in a plane parallel to the plane of the substrate holders (13).

14. Vacuum treatment installation as claimed in claim 13, characterized in that the openings (26) of the treatment chambers (27, 28, 43) are provided with screens (46) for masking the substrates during the treatment.

15. Vacuum treatment installation as claimed in at least one of claims 1 to 14, characterized in that the connecting rod configurations (8, 57) for the advance of the rotatable substrate holders (13) exclusively have articulations with which the substrate holders (13) can be moved without the occurrence of linear sliding friction.

16. Vacuum treatment installation as claimed in claim 5, characterized in that the shortest and upper members (65) of the trapezoidal connecting rod configurations (57) have in their midpoints further articulations, and that in each instance two serially connected trapezoidal connecting rod configurations (57) are connected with one another by means of distance connecting rods (62) such that each of the serially connected trapezoidal connecting rod configurations (57) assumes the same angular position.

17. Vacuum treatment installation as claimed in at least one of claims 5 to 7, characterized in that the driving mechanism (51) for the shaft (56) is disposed in the inner chamber component (16) open to the atmosphere.

18. Vacuum treatment installation as claimed in claim 16, characterized in that the upper members (65) of the trapezoidal connecting rod configurations (57) have fixedly situated further connecting rods (65a), whose lower ends are connected via articulations with extension arms (61) at whose outer ends the substrate holders (13) are fastened.

19. Vacuum treatment installation as claimed in claim 18, characterized in that the upper members (65) and their connecting rods (65a) have the form of a “T”.

20. Vacuum treatment installation as claimed in at least one of claims 16 to 19, characterized in that on the shaft (56) is disposed a bearing flange (63), which acts via connecting rods (64) onto angle levers (59) fulcrumed on the rotary plate (58) and whose one shank is a portion of the particular innermost trapezoidal connecting rod configurations (57) and through which a swiveling of the trapezoidal connecting rod configurations (57) can be brought about.
